(19) United States
(12) Patent Application Publication
(10) Pub. No.: US 2026/0104537 A1
(43) Pub. Date: Apr. 16, 2026

(54) HARD COAT FILM

(71) Applicant: NIPPON PAPER INDUSTRIES CO., LTD., Tokyo (JP)

(72) Inventors: Takeshi HOTTA, Tokyo (JP); Yusuke SUGIYAMA, Tokyo (JP); Ryo KOIKE, Tokyo (JP); Yuki YOKOI, Tokyo (JP); Yosuke SAKASHITA, Tokyo (JP)

(73) Assignee: NIPPON PAPER INDUSTRIES CO., LTD., Tokyo (JP)

(21) Appl. No.: 19/114,922

(22) PCT Filed: Sep. 26, 2023
(86) PCT No.: PCT/JP2023/034990

§ 371 Date: Mar. 25, 2025

(30) Foreign Application Priority Data
Sep. 27, 2022 (JP) 2022-154151

(51) Int. Cl. G02B 1/14; C08J 7/046; C08K 5/3492; H10K 50/844; H10K 59/80

(52) U.S. Cl. CPC G02B 1/14; C08J 7/046; C08K 5/3492; H10K 50/844; H10K 59/873

(57) ABSTRACT

The present invention provides a hard coat film being capable of improving the durability (light resistance) of a light-emitting element of an organic EL display, and suppressing deterioration of a display of the organic EL display, without adversely affecting color and brightness of the display of the organic EL display, when the hard coat film is used as a protective film on a surface of the organic EL display. The hard coat film includes a hard coat layer laminated on at least one surface of a transparent base material, and including an ultraviolet curable resin containing a sesamol-type benzotriazole-based ultraviolet absorbing agent with a weight-average molecular weight in a range of 15000 to 35000, and has light transmittance of less than 1% at a wavelength of 365 nm, less than 10% at a wavelength of 405 nm, and 81% or more at a wavelength of 436 nm.

### TECHNICAL FIELD

The present invention relates to a hard coat film to be used for optical members. In more detail, it relates to a hard coat film that can be used as a protective film for a panel display such as an organic electroluminescence (EL) display device, a liquid crystal display (LCD) device, and a plasma display device, a display device component such as a touch panel, and the like.

### BACKGROUND ART

For example, it is required to provide scratch resistance to a display surface of a display such as an organic electroluminescence (EL) display device, and a liquid crystal display (LCD) device so as not to degrade the visibility due to being damaged during handling. Accordingly, it is common to provide a display surface of a display with scratch resistance by using a hard coat film including a hard coat layer on a base material film.

In recent years, with thinning and lightening of a display, thinning of a component member has been progressing. For example, thinning of a hard coat film used for a polarizing plate of a display is also required.

Furthermore, for example, when the above-mentioned hard coat film is used as a protective film on a surface of an organic EL display, the hard coat film is required to satisfy several requirements: not adversely affecting the color and brightness of the display of the organic EL display, capable of improving the durability (light resistance) of a light emitting element of the organic EL display, capable of suppressing deterioration of the display of the organic EL display, and the like.

As a conventional technology, for example, PTL 1 discloses a film-forming composition including a triazine ring-containing polymer capable of forming a thin film with a high refractive index and excellent light resistance. Also, for example, PTL 2 discloses a film-forming composition including a triazine ring-containing hyperbranched polymer capable of forming a film having high transparency and high light resistance and having a thickness of 1000 nm or more.

### CITATION LIST

### Patent Literature

[PTL 1] International Publication No. WO2017/110810
[PTL 2] International Publication No. WO2013/094664

### SUMMARY OF INVENTION

### Technical Problem

In order to suppress deterioration of some polymers to be used for an organic EL display and damage such as fading and discoloration of dye, it is required to sufficiently reduce the light transmittance at wavelengths of, for example, 365 nm and 405 nm. Furthermore, in recent years, for the purpose of improving durability (light resistance) of a light emitting element of the organic EL display, it has been required to sufficiently reduce the light transmittance at, for example, 405 nm to protect the light emitting element. However, a film obtained from, for example, the film-forming compositions disclosed in the above PTLs 1 and 2, has very high light transmittance at, for example, 365 nm, 405 nm, and cannot solve problems such as suppressing deterioration of some polymers used in the above organic EL displays and damage such as fading and discoloration of dye, and improving the durability (light resistance) of light-emitting elements in organic EL displays.

Furthermore, in addition to the above-mentioned PTLs 1 and 2, various hard coat films of the prior art are known, but it has been difficult to obtain a hard coat film that can simultaneously satisfy the requirements of not adversely affecting the color and brightness of a display of the above-mentioned organic EL display, and being capable of improving the durability (light resistance) of a light-emitting element of the organic EL display, and suppressing deterioration of the display of the organic EL display.

Thus, an object of the present invention is firstly to provide a hard coat film capable of improving the durability (light resistance) of a light-emitting element of an organic EL display, and suppressing deterioration of a display of the organic EL display, without adversely affecting the color and brightness of the display of an organic EL display, when the hard coat film is used as a protective film on a surface of the organic EL display, secondary to provide a hard coat film capable of maintaining the above-mentioned performance also after the hard coat film is subjected to a light resistance test, and thirdly to provide a hard coat film capable of being thinned.

### Solution to Problem

The inventors of the present invention have studied hard to solve the above-mentioned problems, and as a result, they found that the invention having the following configuration can solve the above-mentioned problems.

In other words, the present invention includes the following configuration.

### (First Invention)

A hard coat film including a hard coat layer laminated on at least one surface of a transparent base material, the hard coat layer including an ultraviolet curable resin containing a sesamol-type benzotriazole-based ultraviolet absorbing agent with a weight-average molecular weight in a range of 15000 to 35000, in which the hard coat film has light transmittance of less than 1% at a wavelength of 365 nm, light transmittance of less than 10% at a wavelength of 405 nm, and light transmittance of 81% or more at a wavelength of 436 nm.

### (Second Invention)

The hard coat film according to the first invention, wherein after the hard coat film is subjected to an accelerated light resistance test in accordance with JIS-K-5600-7-7 for 100 hours, the light transmittance at a wavelength of 365 nm is less than 1%, the light transmittance at a wavelength of 405 nm is less than 10%, and the light transmittance at a wavelength of 436 nm is 81% or more.

### (Third Invention)

The hard coat film according to the first or the second invention, wherein a thickness of the hard coat layer is more than 2.0 μm and less than 6.0 μm.

### (Fourth Invention)

The hard coat film according to any one of the first to third inventions, wherein a blending amount of the sesamol-type benzotriazole-based ultraviolet absorbing agent is 20 parts by mass to 60 parts by mass with respect to 100 parts by mass of the ultraviolet curable resin of the hard coat layer.

### (Fifth Invention)

The hard coat film according to any one of the first to fourth inventions, wherein the transparent base material is a triacetyl cellulose film, a polyethylene terephthalate film, or a cycloolefin polymer film.

### (Sixth Invention)

The hard coat film according to the first or second invention, wherein an easy-bonding layer is provided between the transparent base material and the hard coat layer.

### Advantageous Effect of Invention

The present invention can provide a hard coat film capable of improving the durability (light resistance) of the light-emitting element of the organic EL display, and suppressing deterioration of the display of the organic EL display without adversely affecting the color and brightness of the display of the organic EL display, when the hard coat film is used as a protective film on a surface of the organic EL display.

Furthermore, the present invention can provide a hard coat film capable of maintaining the above-mentioned performance also after the hard coat film is subjected to a light resistance test.

Furthermore, the present invention can provide a hard coat film capable of being thinned.

### DESCRIPTION OF EMBODIMENTS

Hereinafter, embodiments for carrying out the present invention will be described in detail, but the present invention is not limited to the following embodiments.

Note here that in the present specification, unless especially stated otherwise, “from xx to yy” means “xx or more and yy or less”.

As in the above-mentioned first invention, a hard coat film of the present invention includes a hard coat layer laminated on at least one surface of a transparent base material, the hard coat layer including an ultraviolet curable resin containing a sesamol-type benzotriazole-based ultraviolet absorbing agent with weight-average molecular weight in a range of 15000 to 35000, and having light transmittance of less than 1% at a wavelength of 365 nm, light transmittance of less than 10% at a wavelength of 405 nm, and light transmittance of 81% or more at a wavelength of 436 nm.

Hereinafter, configurations of the hard coat film of the present invention are described in detail.

### [Transparent Base Material]

Firstly, a transparent base material of the above-mentioned hard coat film is described.

As a base material to be coated for the hard coat film of the present invention, a transparent film base material is usually used.

The transparent film base material used in the present invention is not particularly limited as long as it has transparency, and examples thereof include resin films including acrylic resin, triacetyl cellulose, polyethylene terephthalate, cycloolefin polymer, polycarbonate, polyethylene naphthalate, polyethylene, polytrimethylene terephthalate, polypropylene, polybutylene terephthalate, polybutylene naphthalate, polystyrene, polymethyl methacrylate, polystyrene glycidyl methacrylate, aromatic polyimide, alicyclic polyimide, polyamideimide, and mixtures thereof.

Herein, the “Transparency” Refers to a Total Light Transmittance of 80% or More, Measured in Accordance with JIS-K7136.

In the present invention, from the viewpoints of transparency, optical properties, and versatility in optical films for displays, among these film base materials, a triacetyl cellulose film, a polyethylene terephthalate film, a cycloolefin polymer film, or the like, are particularly suitable.

In the present invention, a thickness of the transparent base material is appropriately selected depending on applications, but from the viewpoint of the demand for thinner hard coat films with the demand for thinner and lighter displays, the thickness is preferably 50 μm or less, and particularly preferably 30 μm or less. On the other hand, from the viewpoint of mechanical strength, handling property, and the like, it is preferably 10 μm or more.

### [Hard Coat Layer]

Next, a hard coat layer of the hard coat film will be described.

In the present invention, the hard coat layer contains at least an ultraviolet curable resin, and a sesamol-type benzotriazole-based ultraviolet absorbing agent having a weight-average molecular weight in a range of 15000 to 35000.

In the present invention, as a resin included in the hard coat layer, an ultraviolet curable resin is preferably used, in particular, from the viewpoint of providing surface hardness (pencil hardness, scratch resistance) of the hard coat layer, being capable of adjusting a degree of crosslinking by an exposure amount of ultraviolet ray, and being capable of adjusting the surface hardness of the hard coat layer.

The ultraviolet curable resin to be used for the present invention is not particularly limited as long as it is a transparent resin that is cured by irradiation of ultraviolet rays (UV). However, in order for the coating film hardness and the hard coat layer to form a three-dimensional cross-linking structure, ones made of UV-curable polyfunctional acrylate having three or more(meth)acryloyloxy groups in one molecule are preferable. Specific examples of the UV-curable polyfunctional acrylate having three or more(meth)acryloyloxy groups in one molecule include trimethylol propane tri(meth) acrylate, pentaerythritol tri(meth) acrylate, pentaerythritol tetra(meth) acrylate, dipentaerythritol tri(meth) acrylate, dipentaerythritol tetra(meth) acrylate, dipentaerythritol penta(meth) acrylate, dipentaerythritol hexa(meth) acrylate, trimethylolpropane ethoxytriacrylate, glycerin propoxy triacrylate, ditrimethylolpropane tetracrylate, and the like. Note here that the polyfunctional acrylate may be used alone or two or more kinds of the polyfunctional acrylates may be used in combination.

Furthermore, the ultraviolet curable resin used in the hard coat layer is preferably a monomer or an oligomer or a polymer having a weight-average molecular weight in the range of 500 to 3600, more preferably a weight-average molecular weight in the range of 500 to 3000, and further more preferably a weight-average molecular weight from 500 to 2400. When the weight-average molecular weight is less than 500, a curing contraction when cured by UV irradiation is large, a phenomenon (curl) in which the hard coat film warps toward the hard coat layer surface side becomes large, and a failure occurs in the subsequent processing process, and the processing suitability becomes poor. Furthermore, the weight-average molecular weight of more than 3600 is not suitable because flexibility of the hard coat layer is enhanced but hardness becomes insufficient.

Note here that, the weight-average molecular weight in the present invention is an average molecular weight obtained in terms of standard polystyrene by gel permeation chromatography (GPC) analysis.

Furthermore, when the ultraviolet curable resin used in the hard coat layer has the weight-average molecular weight of less than 1500, the number of the functional groups in one molecule is desirably 3 or more and less than 10. Furthermore, when the ultraviolet curable resin has the weight-average molecular weight of 1500 or more, the number of the functional groups in one molecule is desirably 3 or more and 20 or less. When in the above range, curl may be suppressed, and appropriate processing suitability may be maintained.

Furthermore, as the resin included in the hard coat layer, a thermoplastic resin such as polyethylene, polypropylene, polystyrene, polycarbonate, polyester, acryl, styrene-acryl, and cellulose, or a thermosetting resin such as a phenolic resin, a urea resin, unsaturated polyester, epoxy, and a silicon resin, in addition to the above-mentioned ultraviolet curable resin, may be blended within a range that does not impair the hardness or the scratch resistance of the hard coat layer.

In the present invention, the above-mentioned hard coat layer contains, in addition to the above-mentioned ultraviolet curable resin, a sesamol-type benzotriazole-based ultraviolet absorbing agent having a weight-average molecular weight in a range of 15000 to 35000 (hereinafter, also referred to as an “ultraviolet absorbing agent of the present invention” in the present specification).

The ultraviolet absorbing agent of the present invention is formed by reacting a sesamol-type benzotriazole-based monomer with, for example, an acrylate resin component to be polymerized.

Herein, the sesamol-type benzotriazole-based monomer is, for example, one represented by the following general formula (I), and is a derivative of a compound in which sesamol is bonded to the nitrogen atom at the 2-position of the benzotriazole ring.

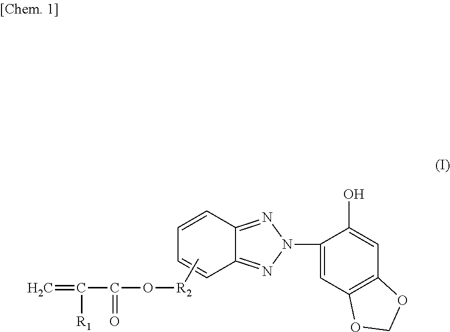

In the above formula, R₁ represents a hydrogen atom or a methyl group, and R₂ represents a linear or branched alkylene group having 1 to 6 carbon atoms, or a linear or branched oxyalkylene group having 1 to 6 carbon atoms.

Specific examples of the sesamol-type benzotriazole-based monomer represented by the above general formula (I) include 2-[2-(6-hydroxybenzo[1,3]dioxol-5-yl)-2H-benzotriazol-5-yl]ethyl methacrylate, 2-[2-(6-hydroxybenzo[1,3]dioxol-5-yl)-2H-benzotriazol-5-yl]ethyl acrylate, 3-[2-(6-hydroxybenzo[1,3]dioxol-5-yl)-2H-benzotriazol-5-yl]propyl methacrylate, 3-[2-(6-hydroxybenzo[1,3]dioxol-5-yl)-2H-benzotriazol-5-yl]propyl acrylate, 4-[2-(6-hydroxybenzo[1,3]dioxol-5-yl)-2H-benzotriazol-5-yl]butyl methacrylate, 4-[2-(6-hydroxybenzo[1,3]dioxol-5-yl)-2H-benzotriazol-5-yl]butyl acrylate, 2-[2-(6-hydroxybenzo[1,3]dioxol-5-yl)-2H-benzotriazol-5-yloxy]ethyl methacrylate, 2-[2-(6-hydroxybenzo[1,3]dioxol-5-yl)-2H-benzotriazol-5-yloxy]ethyl acrylate, 2-[3-{2-(6-hydroxybenzo[1,3]dioxol-5-yl)-2H-benzotriazol-5-yl}propanoyloxy]ethyl methacrylate, 2-[3-{2-(6-hydroxybenzo[1,3]dioxol-5-yl)-2H-benzotriazol-5-yl}propanoyloxy]ethyl acrylate, 4-[3-{2-(6-hydroxybenzo[1,3]dioxol-5-yl)-2H-benzotriazol-5-yl}propanoyloxy]butyl methacrylate, 4-[3-{2-(6-hydroxybenzo[1,3]dioxol-5-yl)-2H-benzotriazol-5-yl}propanoyloxy]butyl acrylate, 2-(methacryloyloxy)ethyl-2-(6-hydroxybenzo[1,3]dioxol-5-yl)-2H-benzotriazole-5-carboxylate, 2-(acryloyloxy)ethyl-2-(6-hydroxybenzo[1,3]dioxol-5-yl)-2H-benzotriazole-5-carboxylate, 4-(methacryloyloxy)butyl-2-(6-hydroxybenzo[1,3]dioxol-5-yl)-2H-benzotriazole-5-carboxylate, 4-(acryloyloxy)butyl-2-(6-hydroxybenzo[1,3]dioxol-5-yl)-2H-benzotriazole-5-carboxylate, and the like.

The ultraviolet absorbing agent of the present invention can be obtained by polymerizing the above-mentioned sesamol-type benzotriazole-based monomer with another monomer component (for example, an acrylate resin component such as methyl(meth) acrylate, ethyl (meth)acrylate, propyl(meth) acrylate, isopropyl(meth) acrylate, butyl(meth) acrylate, isobutyl(meth) acrylate, t-butyl(meth) acrylate, octyl(meth) acrylate, nonyl(meth) acrylate, and the like). The polymerization method can be a conventionally known solution polymerization method, an emulsion polymerization method, a suspension polymerization method, a bulk polymerization method, and the like.

In the present invention, it is important to use a sesamol-type benzotriazole-based ultraviolet absorbing agent having a weight-average molecular weight in the range of 15000 to 35000.

On the contrary, when a sesamol-type benzotriazole-based ultraviolet absorbing agent having a weight-average molecular weight of less than 15000 is used, since the light transmittance at 405 nm cannot be sufficiently reduced, as shown in the comparative example described later, the display of the organic EL display may be deteriorated. Furthermore, when a sesamol-type benzotriazole-based ultraviolet absorbing agent having a weight-average molecular weight of more than 35000 is used, the performance cannot be maintained also after a light resistance test at a wavelength of 405 nm, and this causes a problem of deterioration of the display of the organic EL display and a problem of failure to achieve improvement in the durability (light resistance) of the light emitting element.

Note here that the weight-average molecular weight of the above-mentioned sesamol-type benzotriazole-based ultraviolet absorbing agent is an average molecular weight obtained in terms of standard polystyrene by gel permeation chromatography (GPC) analysis.

The ultraviolet absorbing agent of the present invention may be used alone or two or more kinds of the ultraviolet absorbing agents may be used in combination.

Furthermore, as long as the effects of the present invention are not impaired, for example, other benzotriazole-based ultraviolet absorbing agents, hydroxyphenyltriazine-based ultraviolet absorbing agents, and the like, may be used in combination.

In the hard coat film of the present invention, when the hard coat layer contains the above-mentioned ultraviolet absorbing agent of the present invention, the spectral characteristics (light transmittance at wavelengths of 365 nm, 405 nm, and 436 nm) can satisfy the range of the present invention.

As described later, in the present invention, a thickness of the hard coat layer containing the ultraviolet absorbing agent of the present invention is preferably more than 2.0 μm and less than 6.0 μm, and particularly preferably in the range of 3.0 μm to 5.0 μm. When the thickness of the hard coat layer is more than 2.0 μm and less than 6.0 μm, the blending amount of the ultraviolet absorbing agent of the present invention is preferably in the range of 20 parts by mass to 60 parts by mass with respect to 100 parts by mass of the ultraviolet curable resin of the hard coat layer. When the blending amount of the ultraviolet absorbing agent of the present invention is less than 20 parts by mass, the spectral characteristics of the present invention cannot be sufficiently satisfied within the range of the thickness of the hard coat layer of the present invention of more than 2.0 μm and less than 6.0 μm. On the other hand, it is not suitable that the blending amount of the ultraviolet absorbing agent of the present invention is more than 60 parts by mass because the ratio of the ultraviolet curable resin in the hard coat layer decreases, and adhesion of the hard coat layer to the film base material may decrease, or the hardness of the hard coat layer may decrease.

Furthermore, when the thickness of the hard coat layer is in a range of 3.0 μm to 5.0 μm, the blending amount of the ultraviolet absorbing agent of the present invention is preferably in the range of 30 parts by mass to 50 parts by mass with respect to 100 parts by mass of the ultraviolet curable resin of the hard coat layer.

Furthermore, it is also possible to further improve the surface hardness (scratch resistance) by allowing the hard coat layer to contain inorganic oxide fine particles. In this case, an average particle diameter of the inorganic oxide fine particles is preferably in the range of 5 to 50 nm, and the average particle diameter is more preferably in the range of 10 to 40 nm. When the average particle diameter is less than 5 nm, it is difficult to obtain sufficient surface hardness. On the other hand, when the average particle diameter is more than 50 nm, gloss and transparency of the hard coat layer easily degrade, and the flexibility may also degrade.

In the present invention, examples of the inorganic oxide fine particles may include alumina and silica. Among these, alumina is particularly suitable because alumina mainly including aluminum has high hardness and exhibits an effect at a smaller addition amount than silica.

In the present invention, a content of the inorganic oxide fine particles is preferably from 0.1 to 10.0 parts by mass with respect to 100 parts by mass of the ultraviolet curable resin of the hard coat layer. When the content of the inorganic oxide fine particles is less than 0.1 parts by mass, it is difficult to obtain an effect of improving the surface hardness (scratch resistance). On the other hand, the content of more than 10.0 parts by mass is not preferable because a haze increases.

A hard coat coating material for forming the hard coat layer can include a photopolymerization initiator. Examples of such a photopolymerization initiator include acetophenones such as commercially available IRGACURE 651 and IRGACURE 184 (both are trade name, manufactured by BASF), and benzophenones such as IRGACURE 500 (trade name, manufactured by BASF).

For the hard coat layer, a levelling agent may be used to improve the coating property. For example, well-known levelling agents such as a fluorine-based leveling agent, an acryl-based leveling agent, a siloxane-based leveling agent and adducts thereof or mixtures thereof may be used. As a blending amount, the levelling agent can be blended in the range of 0.03 to 3.0 parts by mass relative to 100 parts by mass of the solid content of resin of the hard coat layer. Furthermore, in applications for touch panels or the like, when an anti-bonding property using an optically transparent adhesive agent OCR is required for the purpose of bonding with a cover glass (CG), a transparent conductive member (TSP), a liquid crystal module (LCM), or the like, of a touch panel terminal, an acrylic-based levelling agent or a fluorine-based levelling agent having high surface free energy (about 30 mN/m or more) is preferably used.

As the other additives to be blended to the hard coat layer, a defoaming agent, a surface tension controlling agent, an antifouling agent, an antioxidant, an antistatic agent, a light stabilizer, or the like, may be added if necessary, in the range that does not impair the effect of the present invention.

The hard coat layer is formed by coating the hard coat coating material in which the above-mentioned ultraviolet absorbing agent of the present invention, a photopolymerization initiator, other additive, or the like, in addition to the ultraviolet curable resin described above, is dissolved or dispersed in a suitable solvent, and drying thereof and irradiated with UV on the transparent base material layer. As the solvent, any solvent can be appropriately selected depending on the solubility of the resin to be blended as long as the solvent is capable of uniformly dissolving or dispersing at least the solid content (resin, an ultraviolet absorbing agent, dye, polymerization initiator, and other additives). As such a solvent, a well-known organic solvent can be used alone or an appropriate number of types of the organic solvents can be used in combination. Examples of the solvent include: aromatic-based solvents such as toluene, xylene, and n-heptane: aliphatic-based solvents such as cyclohexane, methyl cyclohexane, and ethyl cyclohexane; ester-based solvents such as methyl acetate, ethyl acetate, propyl acetate, isopropyl acetate, butyl acetate, and methyl lactate; ketone-based solvents such as acetone, methyl ethyl ketone, methyl isobutyl ketone, and cyclohexanone; and alcohol-based solvents such as methanol, ethanol, isopropyl alcohol, and n-propyl alcohol.

The coating method of the hard coat coating material for forming the hard coat layer is not particularly limited. A well-known coating method such as a gravure coating, a micro gravure coating, a fountain-bar coating, a slide die coating, a slot die coating, a screen printing method, or a spray coating method may be used for coating, followed by drying usually at a temperature of about 50 to 120° C.

The irradiation dose of ultraviolet rays (UV) after formation of the coating film of the hard coat layer may be an irradiation dose necessary to provide full hardness of the hard coat layer, and can be appropriately set depending on the type of the ultraviolet curable resin.

In the present invention, a thickness (coating film thickness) of the hard coat layer is, for example, preferably more than 2.0 μm and less than 6.0 μm, and more preferably in a range of 3.0 μm to 5.0 μm.

It is not preferable that the thickness of the hard coat layer is less than 2.0 μm, because necessary hardness (for example, scratch resistance) is degraded. Furthermore, it is not preferable that the thickness of the coat layer is 6.0 μm or more because curl occurs strongly resulting in degradation of handling property in the manufacturing process or the like and from the viewpoint of thinning the hard coat film.

Note here that the hard coat film of the present invention is formed by laminating the above-mentioned hard coat layer on at least one side of a transparent base material. For example, when a cycloolefin polymer film is used as the transparent base material, it is also suitable to provide an easy-adhesion layer between the transparent base material and the hard coat layer in order to improve the adhesion of the hard coat layer.

The resin used in the easy-adhesion layer can be any resin that forms a coated film, without any particular limitation. For example, from the viewpoint of adhesion to the transparent base material film (cycloolefin film), polyolefin-based resins, acrylic-based resins such as styrene-acrylic resins and methyl methacrylate resins, epoxy-based resins, isocyanate-based resins, cellulose-based resins, or mixtures of two or more of these resins can be preferably used.

A coating film thickness of the easy-adhesion layer is not particularly limited, but is preferably in the range of 0.1 μm to 5.0 μm, which does not adversely affect the adhesion to the base film and the hard coat layer, or the pencil hardness of the hard coat layer.

As described above, the hard coat film of the present invention is formed by laminating a hard coat layer including an ultraviolet curable resin containing a sesamol-type benzotriazole-based ultraviolet absorbing agent with a weight-average molecular weight in the range of 15000 to 35000 on at least one side of a transparent base material.

The hard coat film of the present invention further satisfies the following spectral characteristics.

In other words, the hard coat film of the present invention has the light transmittance of less than 1% at a wavelength of 365 nm, the light transmittance of less than 10% at a wavelength of 405 nm, and the light transmittance of 81% or more at a wavelength of 436 nm.

Note here that the specific method for measuring the light transmittance at each of the above wavelengths will be described in the description of the Examples described below.

The hard coat film of the present invention is provided with a hard coat layer including an ultraviolet curable resin containing the ultraviolet absorbing agent of the present invention, and the above-mentioned spectral characteristics (light transmittance at wavelengths of 365 nm, 405 nm, and 436 nm) satisfy the range of the present invention, so that the light transmittance at wavelengths represented by 365 nm and 405 nm, which cause deterioration of some polymers used in an organic EL display and damage such as fading and discoloration of dye, can be suppressed to less than 10%, and deterioration of some polymers or damages such as fading and discoloration of dye can be suppressed. Furthermore, in order to improve the durability (light resistance) of the light emitting elements of recent organic EL displays, it is required to sufficiently reduce the light transmittance at 405 nm to protect the light emitting elements, and the hard coat film of the present invention can suppress the light transmittance at a wavelength of 405 nm to less than 10%, and can improve the durability (light resistance) of the light emitting elements of recent organic EL displays. In addition, at the wavelength of 436 nm in the visible light region, the light transmittance is required to be maximized to ensure the brightness of the display of an organic EL display, but the hard coat film of the present invention makes it possible to obtain a light transmittance of 81% or more at the wavelength of 436 nm in the visible light region, and does not adversely affect the brightness of the display of an organic EL display.

Furthermore, in the hard coat film of the present invention, after the hard coat film is subjected to an accelerated light resistance test in accordance with JIS-K-5600-7 7 for 100 hours, the light transmittance at a wavelength of 365 nm is less than 1%, the light transmittance at a wavelength of 405 nm is less than 10%, and the light transmittance at a wavelength of 436 nm is 81% or more.

Note here that the above light resistance test will be described in more detail in the Examples described below.

The light transmittance at each of the above-mentioned wavelengths, from the purpose thereof, needs to maintain the performance also after the light resistance test, at wavelengths of 365 nm and 405 nm, which cause deterioration of some polymers or damages such as fading and discoloration of dye, and at a wavelength of 405 nm contributing to protection of the light emitting element of the recent organic EL display. The hard coat film of the present invention is provided with a hard coat layer including an ultraviolet curable resin containing the ultraviolet absorbing agent of the present invention, and thereby can suppress the increase in the light transmittance at wavelengths of 365 nm and 405 nm even after the light resistance test, and can suppress deterioration of the display of the organic EL display. Note here that also at a wavelength of 436 nm in the visible light region, the hard coat film of the present invention can suppress the increase in the light transmittance also after the light resistance test, and can maintain the brightness of the display of the organic EL display.

As described above in detail, the present invention can obtain a hard coat film capable of improving the durability (light resistance) of the light emitting element of the organic EL display and suppressing deterioration of the display of the organic EL display, without adversely affecting the color and brightness of the display of the organic EL display, when the hard coat film is used as a protective film on a surface of the organic EL display. Furthermore, according to the present invention, it is possible obtain a hard coat film capable of maintaining the above-mentioned performance also after a light resistance test. Furthermore, according to the present invention, a hard coat film capable of being thinned can be obtained.

### EXAMPLES

Next, embodiments of the present invention will be specifically described in more detail with reference to Examples, but the present invention is not limited to the following Examples.

Note here that unless otherwise particularly noted, “part” represents “part by mass”, and “%” represents “% by mass”, in the below description.

### Example 1

### [Preparation of Coating Solution for Forming Hard Coat Layer]

A coating solution for forming a hard coat layer (hereinafter, also referred to as “hard coat coating material”) having a final solid concentration of 30% was prepared by blending 94 parts of an acrylate-based ultraviolet curable resin coating material containing a sesamol-type benzotriazole-based ultraviolet absorbing agent of the present invention (HFC-UVA-13 (trade name); manufactured by Harima Chemicals Groups, Inc.; weight-average molecular weight of the sesamol-type benzotriazole-based ultraviolet absorbing agent: 22000) as a main component, 5 parts of IRGACURE 184 (photopolymerization initiator, manufactured by BASF), and 1 part of a surface modifier (Ftergent 681; manufactured by Neos Co., Ltd.), and diluting the resultant product with toluene/propylene glycol monomethyl ether acetate of 15/85 (parts by weight).

### [Production of Hard Coat Film]

The above-mentioned hard coat coating material was applied to one side of a 25 μm-thick triacetyl cellulose film TJ25 UL (manufactured by Fujifilm Corporation) using a bar coater, and the film was dried with hot air in a drying oven at 80° C. for 1 minute to form a coating layer with a coating film thickness of 3.0 μm. This was cured by irradiating with ultraviolet rays at a UV dose of 100 mJ/cm² using a UV irradiation device set at a height of 60 mm from the coated surface, so as to produce the hard coat film of this Example 1.

### Example 2

A hard coat film of Example 2 was prepared in the same manner as in Example 1 by applying a hard coat coating material prepared in the same manner as in Example 1 except that an acrylate-based ultraviolet curable resin coating material containing the sesamol-type benzotriazole-based ultraviolet absorbing agent of the present invention (HFC-UVA-13 (trade name); manufactured by Harima Chemicals Groups, Inc.; weight-average molecular weight of the sesamol-type benzotriazole-based ultraviolet absorbing agent: 27000) was used as the acrylate-based ultraviolet curable resin coating material.

### Example 3

A hard coat film of Example 3 was prepared in the same manner as in Example 1 by applying a hard coat coating material prepared in the same manner as in Example 1 except that an acrylate-based ultraviolet curable resin coating material containing the sesamol-type benzotriazole-based ultraviolet absorbing agent of the present invention (HFC-UVA-13 (trade name); manufactured by Harima Chemicals Groups, Inc.; weight-average molecular weight of the sesamol-type benzotriazole-based ultraviolet absorbing agent: 35000) was used as the acrylate-based ultraviolet curable resin coating material.

### Example 4

A hard coat film of Example 4 was prepared in the same manner as in Example 1 by applying a hard coat coating material prepared in the same manner as in Example 1 except that an acrylate-based ultraviolet curable resin coating material containing the sesamol-type benzotriazole-based ultraviolet absorbing agent of the present invention (HFC-UVA-13 (trade name); manufactured by Harima Chemicals Groups, Inc.: weight-average molecular weight of the sesamol-type benzotriazole-based ultraviolet absorbing agent: 15000) was used as the acrylate-based ultraviolet curable resin coating material.

### Example 5

A hard coat film of Example 5 was prepared in the same manner as in Example 1 except that the hard coat coating material of Example 1 was used and the base material was changed to A4360 (manufactured by Toyobo Co., Ltd.) having a thickness of 50 μm as a polyethylene terephthalate film.

### Example 6

A hard coat film of Example 6 was prepared in the same manner as in Example 1 except that the hard coat coating material of Example 1 was used and the base material was changed to Zeonorfilm ZF12 (manufactured by Zeon Corporation) having a thickness of 13 μm as a cycloolefin polymer film.

### Example 7

A hard coat film of Example 7 was prepared in the same manner as in Example 1 except that the hard coat coating material of Example 1 was used and the base material was changed to Zeonorfilm ZD12 (manufactured by Zeon Corporation) having a thickness of 22 μm as a cycloolefin polymer film.

### Example 8

A hard coat film of Example 8 was prepared in the same manner as in Example 1 except that the hard coat coating material of Example 1 was used and the base material was changed to Zeonorfilm ZD12 (manufactured by Zeon Corporation) having a thickness of 26 μm as a cycloolefin polymer film.

### Example 9

A hard coat film of Example 9 was prepared in the same manner as in Example 8 except that a thickness of the coating film of the coating layer in Example 8 was changed to 5.0 μm.

### Comparative Example 1

### [Preparation of Hard Coat Coating Material]

A hard coat coating material having a final solid concentration of 30% was prepared by blending 94 parts of an acrylate-based ultraviolet curable resin coating material containing a sesamol-type benzotriazole-based ultraviolet absorbing agent (HFC-UVA-13 (trade name); manufactured by Harima Chemicals Groups, Inc., weight-average molecular weight of the sesamol-type benzotriazole-based ultraviolet absorbing agent: 13000) as a main component, 5 parts of IRGACURE 184 (photopolymerization initiator, manufactured by BASF), and 1 part of a surface modifier (Ftergent 681; manufactured by NEOS Co., Ltd.), and diluting the resultant product with toluene/propylene glycol monomethyl ether acetate of 15/85 (parts by weight).

### [Production of Hard Coat Film]

A hard coat film of Comparative Example 1 was produced in the same manner as in Example 1 except that the hard coat coating material including the above-mentioned composition was used.

### Comparative Example 2

A hard coat film of Comparative Example 2 was produced in the same manner as in Comparative Example 1 except that a thickness of a coating film of the coating layer in Comparative Example 1 was changed to 5.0 μm.

### Comparative Example 3

A hard coat film of Comparative Example 3 was produced in the same manner as in Comparative Example 1 by applying the hard coat coating material prepared in the same manner as in Comparative Example 1 except that the acrylate-based ultraviolet curable resin coating material containing a sesamol-type benzotriazole-based ultraviolet absorbing agent (HFC-UVA-13 (trade name); manufactured by Harima Chemicals Groups, Inc.; weight-average molecular weight of the sesamol-type benzotriazole-based ultraviolet absorbing agent: 37000) was used as the acrylate-based ultraviolet curable resin coating material.

### Comparative Example 4

A hard coat film of Comparative Example 4 was prepared in the same manner as in Comparative Example 3 except that a thickness of the coating film of the coating layer of Comparative Example 3 was changed to 5.0 μm.

### Comparative Example 5

### [Preparation of Hard Coat Coating Material]

A hard coat coating material having a final solid concentration of 30% was prepared by blending 84 parts of an acrylate-based ultraviolet curable resin (NK Ester A-9550 (trade name); manufactured by Shin-Nakamura Chemical Co., Ltd.) as the main component, 10 parts of a benzotriazole-based ultraviolet absorbing agent (ADK STAB LA-36 (trade name); manufactured by ADEKA Corporation), 5 parts of IRGACURE184 (photopolymerization initiator, manufactured by BASF), and 1 part of a surface modifier (Ftergent 681; manufactured by NEOS Co., Ltd.), and diluting the resulting product with toluene/propylene glycol monomethyl ether acetate of 15/85 (parts by weight).

### [Production of Hard Coat Film]

A hard coat film of Comparative Example 5 was prepared in the same manner as in Example 1 except that the hard coat coating material including the above composition was used.

### Comparative Example 6

### [Preparation of Hard Coat Coating Material]

A hard coat coating material having a final solid concentration of 30% was prepared by blending 90 parts of an acrylate-based ultraviolet curable resin (NK Ester A-9550 (trade name); manufactured by Shin-Nakamura Chemical Co., Ltd.) as the main component, 4 parts of a cyanine dye (NK-9994 (trade name); manufactured by Hayashibara Co., Ltd.), 5 parts of IRGACURE 184 (photopolymerization initiator, manufactured by BASF), and 1 part of a surface modifier (Ftergent 681: manufactured by Neos Co., Ltd.), and diluting the resultant product with toluene/propylene glycol monomethyl ether acetate of 15/85 (parts by weight).

### [Production of Hard Coat Film]

A hard coat film of Comparative Example 6 was prepared in the same manner as in Example 1, except that the hard coat coating material having the above composition was used.

### <Evaluation>

The hard coat films of the Examples and Comparative Examples prepared as described above were evaluated for the following items. The results are shown in Table 1.

### <Thickness of Coating Film>

A formation thickness of a coating film of the hard coat layer (HC layer) was measured using a Thin-Film Analyzer F20 (trade name) (manufactured by FILMETRICS).

### <Light Transmittance at Each Wavelength>

The light transmittance of the hard coat film at each wavelength (365 nm, 405 nm, 436 nm) was measured using a spectrophotometer U-3310 manufactured by Hitachi High-Tech Corporation. The measurement was performed in the wavelength range from 250 to 800 nm at a scan speed of 600 nm/min.

### <Light Resistance Test

Each of the hard coat films produced in the Examples and Comparative Examples was subjected to an accelerated light resistance test by Xenon Weather Ometer (executed in accordance with JIS-K-5600-7-7 under the following conditions).
Light source: Xenon arc
Temperature: 63° C.
Relative humidity: 50%
Irradiance: 50 W/m²
Radiation time: 100 hours
Rainfall cycle and time: Not set

Note here that the light transmittance of the hard coat film at each wavelength after the light resistance test was measured in the same manner as mentioned above.

TABLE 1

| | | | | | Light transmittance (%) | | |
|---|---|---|---|---|---|---|---|
| | Thickness | Light transmittance (%) | | | at each wavelength after | | |
| | of HC | at each wavelength | | | light resistance test | | |
| | layer | 365 | 405 | 436 | 365 | 405 | 436 |
| Table 1 | (μm) | nm | nm | nm | nm | nm | nm |
| Ex. 1 | 3 | 0.1 | 5.3 | 86.6 | 0.1 | 8.8 | 86.0 |
| Ex. 2 | 3 | 0.1 | 5.2 | 85.2 | 0.1 | 8.2 | 85.4 |
| Ex. 3 | 3 | 0.1 | 5.4 | 86.3 | 0.1 | 8.6 | 85.5 |
| Ex. 4 | 3 | 0.1 | 5.8 | 85.7 | 0.1 | 9.4 | 85.1 |
| Ex. 5 | 3 | 0.1 | 6.3 | 84.0 | 0.1 | 9.7 | 83.8 |
| Ex. 6 | 3 | 0.0 | 5.2 | 85.9 | 0.0 | 8.6 | 85.4 |
| Ex. 7 | 3 | 0.0 | 5.4 | 86.4 | 0.0 | 8.4 | 85.6 |
| Ex. 8 | 3 | 0.0 | 5.4 | 86.4 | 0.0 | 8.5 | 86.0 |
| Ex. 9 | 5 | 0.0 | 1.5 | 83.4 | 0.0 | 3.9 | 82.1 |
| CoEx. 1 | 3 | 0.0 | 21.2 | 88.8 | 0.0 | 42.6 | 88.0 |
| CoEx. 2 | 5 | 0.0 | 7.5 | 86.8 | 0.0 | 38.6 | 86.2 |
| CoEx. 3 | 3 | 0.0 | 5.9 | 86.5 | 0.0 | 10.9 | 84.4 |
| CoEx. 4 | 5 | 0.0 | 1.4 | 83.2 | 0.0 | 7.0 | 80.8 |
| CoEx. 5 | 3 | 0.0 | 70.3 | 92.5 | 0.0 | 74.0 | 92.5 |
| CoEx. 6 | 3 | 0.1 | 2.3 | 85.6 | 1.3 | 81.2 | 89.9 |

As is apparent from the results in Table 1 above, each of the hard coat films of Examples of the present invention includes a hard coat layer including an ultraviolet curable resin containing the ultraviolet absorbing agent of the present invention, in which the above-mentioned spectral characteristics (light transmittance at each wavelength of 365 nm, 405 nm, and 436 nm) satisfy the range of the present invention, so that the light transmittance at wavelengths represented by 365 nm and 405 nm, which cause deterioration of some polymers used in an organic EL display or damages such as fading and discoloration of dye, can be suppressed to less than 10%, and deterioration of some polymers or damages such as fading and discoloration of dye can be suppressed. Furthermore, for the purpose of improving the durability (light resistance) of the light emitting elements of recent organic EL displays, it is required to sufficiently reduce the light transmittance at 405 nm to protect the light emitting elements, and the hard coat films of Examples of the present invention can suppress the light transmittance at a wavelength of 405 nm to less than 10%, and can improve the durability (light resistance) of the light emitting elements of recent organic EL displays. In addition, at the wavelength of 436 nm in the visible light region, the light transmittance is required to be maximized to ensure the brightness of the display of the organic EL display, and the hard coat films of Examples of the present invention make it possible to obtain a light transmittance of 81% or more at the wavelength of 436 nm in the visible light region, and does not adversely affect the brightness of the display of the organic EL display.

Furthermore, the light transmittance at each of the above-mentioned wavelengths, from the purpose thereof, needs to maintain its performance even after the light resistance test at wavelengths of 365 nm and 405 nm, which cause deterioration of some polymers or damages such as fading and discoloration of dye, and at a wavelength of 405 nm, which contributes to protection of the light emitting elements of the recent organic EL displays. The hard coat films of Examples of the present invention have a hard coat layer including an ultraviolet-curable resin containing the sesamol-type benzotriazole-based ultraviolet absorbing agent of the present invention, so that the increase in the light transmittance at wavelengths of 365 nm and 405 nm can be suppressed even after the light resistance test, and the deterioration of the display of the organic EL display can be suppressed. Note here that the hard coat films of Examples of the present invention can also suppress the increase in the light transmittance at a wavelength of 436 nm in the visible light region even after the light resistance test, and the brightness of the display of the organic EL display can be maintained.

On the contrary, in the hard coat film of Comparative Example 1 including a hard coat layer including an ultraviolet curable resin containing a sesamol-type benzotriazole-based ultraviolet absorbing agent with a weight-average molecular weight of less than 15000, since the light transmittance at 405 nm cannot be sufficiently reduced, resulting in a problem of deterioration of the display of the organic EL display. Furthermore, in the hard coat film of Comparative Example 2, although the light transmittance at 405 nm can be reduced by adjusting (thickening) the film thickness of the hard coat layer of Comparative Example 1, the performance cannot be maintained at a wavelength of 405 nm even after the light resistance test, resulting in a problem of deterioration of the display of the organic EL display and a problem of failure to achieve improvement in durability (light resistance) of the light emitting element. Note here that there are some methods for further thickening the film thickness of the hard coat layer (for example, 6.0 μm or more) and maintaining the performance at a wavelength of 405 nm even after a light resistance test, but thickening of the hard coat layer is not preferable because it is reverse to the technology trend of thinning the hard coat film, curling the hard coat film, and cracking the hard coat layer.

Furthermore, the hard coat film of Comparative Example 3, which includes a hard coat layer including an ultraviolet curable resin containing a sesamol-type benzotriazole-based ultraviolet absorbing agent with a weight-average molecular weight of more than 35000, cannot maintain the performance at a wavelength of 405 nm even after the light resistance test, resulting in a problem of deterioration of the display of the organic EL display and a problem of failure to achieve improvement in durability (light resistance) of the light-emitting element. Furthermore, in the hard coat film of Comparative Example 4, although the performance can be maintained at a wavelength of 405 nm after the light resistance test by adjusting (thickening) the film thickness of the hard coat layer of Comparative Example 3, the performance at a wavelength of 436 nm cannot be maintained after the light resistance test, resulting in a problem of insufficient brightness of the display of the organic EL display. Note here that there are some methods for further thickening the film thickness of the hard coat layer (for example, 6.0 μm or more) and maintaining the performance at a wavelength of 436 nm even after a light resistance test, but thickening of the hard coat layer is not preferable because it is reverse to the technology trend of thinning the hard coat film, curling the hard coat film, and cracking the hard coat layer.

Furthermore, in the hard coat film of Comparative Example 5 using an ultraviolet absorbing agent other than the ultraviolet absorbing agent of the present invention, since the light transmittance at a wavelength of 405 nm cannot be sufficiently reduced, there is a problem that protection of the organic EL display cannot be achieved. Furthermore, in the hard coat film of Comparative Example 6 not using the ultraviolet absorbing agent of the present invention, although there is no problem with the initial light transmittance at each wavelength, the change in light transmittance at each wavelength after the light resistance test is very large, and there is a problem that improvement in durability (light resistance) of the light emitting element of the organic EL display cannot be achieved.

1. A hard coat film comprising a hard coat layer laminated on at least one surface of a transparent base material, the hard coat layer comprising an ultraviolet curable resin comprising a sesamol-type benzotriazole-based ultraviolet absorbing agent with a weight-average molecular weight in a range of 15000 to 35000, the hard coat film having light transmittance of less than 1% at a wavelength of 365 nm, light transmittance of less than 10% at a wavelength of 405 nm, and light transmittance of 81% or more at a wavelength of 436 nm.

2. The hard coat film according to claim 1, wherein after the hard coat film is subjected to an accelerated light resistance test in accordance with JIS-K-5600-7-7 for 100 hours, the light transmittance at a wavelength of 365 nm is less than 1%, the light transmittance at a wavelength of 405 nm is less than 10%, and the light transmittance at a wavelength of 436 nm is 81% or more.

3. The hard coat film according to claim 1, wherein a thickness of the hard coat layer is more than 2.0 μm and less than 6.0 μm.

4. The hard coat film according to claim 1, wherein a blending amount of the sesamol-type benzotriazole-based ultraviolet absorbing agent is 20 parts by mass to 60 parts by mass with respect to 100 parts by mass of the ultraviolet curable resin of the hard coat layer.

5. The hard coat film according to claim 1, wherein the transparent base material is a triacetyl cellulose film, a polyethylene terephthalate film, or a cycloolefin polymer film.

6. The hard coat film according to claim 1, wherein an easy-bonding layer is provided between the transparent base material and the hard coat layer.

7. The hard coat film according to claim 2, wherein a thickness of the hard coat layer is more than 2.0 μm and less than 6.0 μm.

8. The hard coat film according to claim 2, wherein a blending amount of the sesamol-type benzotriazole-based ultraviolet absorbing agent is 20 parts by mass to 60 parts by mass with respect to 100 parts by mass of the ultraviolet curable resin of the hard coat layer.

9. The hard coat film according to claim 2, wherein the transparent base material is a triacetyl cellulose film, a polyethylene terephthalate film, or a cycloolefin polymer film.

10. The hard coat film according to claim 2, wherein an easy-bonding layer is provided between the transparent base material and the hard coat layer.
